(19) United States
(12) Patent Application Publication
(10) Pub. No.: US 2024/0288746 A1
(43) Pub. Date: Aug. 29, 2024

(54) TECHNOLOGIES FOR DUAL-FREQUENCY COMB SOURCES

(71) Applicants: Nicholas LAMBERT, Dunedin (NZ); Luke TRAINOR, Dunedin (NZ); Harald SCHWEFEL, Dunedin (NZ); OTAGO INNOVATION LIMITED, Dunedin (NZ)

(72) Inventors: Nicholas Lambert, Dunedin (NZ); Luke Trainor, Dunedin (NZ); Harald Schwefel, Dunedin (NZ)

(21) Appl. No.: 18/573,334

(22) PCT Filed: Jun. 28, 2022
(86) PCT No.: PCT/IB2022/056000

§ 371 Date: Dec. 21, 2023

Related U.S. Application Data
(60) Provisional application No. 63/216,484, filed on Jun. 29, 2021.

(51) Int. Cl. G02F 1/35; G01S 7/481; G02F 1/37; H01S 5/00

(52) U.S. Cl. CPC G02F 1/3501; G01S 7/4815; G02F 1/3534; G02F 1/37; H01S 5/0085; G02F 2202/20; G02F 2203/15; G02F 2203/56

(57) ABSTRACT

Techniques dual-frequency comb sources are disclosed. In the illustrative embodiment, a whispering-gallery-mode resonator supports a family of radially-polarized modes and a family of axially-polarized modes. A laser excites one radially-polarized mode and one axial-polarized mode. A microwave field is applied at a free spectral range for each family of modes, coupling the radially-polarized and axially-polarized mode excited by the laser with other modes in the family, creating a dual-frequency comb in the resonator.

### CROSS REFERENCE TO RELATED APPLICATIONS

This application claims the benefit of U.S. provisional patent application No. 63/216,484 filed Jun. 29, 2021, and entitled “TECHNOLOGIES FOR DUAL-FREQUENCY COMB SOURCES.” The disclosure of the prior application is considered part of and is hereby incorporated by reference in its entirety in the disclosure of this application.

### BACKGROUND

Frequency combs that emit optical intensity pulses with a stable repetition rate are a link between time and frequency measurements. Frequency combs have a wide range of uses including frequency multiplexing of telecommunications signals, optical frequency atomic clocks, calibration of astronomical instrumentation, and low noise generation of microwave frequencies.

The addition of another comb, with a slightly different repetition rate, results in a so-called dual comb and opens up further possible applications. Dual frequency combs can be applied two-way time transfer, coherent anti-Stokes Raman spectro-imaging, and highly sensitive range-finding. By measuring the beat frequencies between close-in-frequency comb lines, spectroscopic analysis can take place in the radiofrequency part of the electromagnetic spectrum, allowing fast and economical measurement.

### BRIEF DESCRIPTION OF THE DRAWINGS

The concepts described herein are illustrated by way of example and not by way of limitation in the accompanying figures. For simplicity and clarity of illustration, elements illustrated in the figures are not necessarily drawn to scale. Where considered appropriate, reference labels have been repeated among the figures to indicate corresponding or analogous elements.

FIG. 1 is a simplified diagram of a system with a whispering-gallery-mode resonator in a microwave resonator.

FIG. 2 is a spectrum of radially-polarized and axially-polarized modes of the whispering-gallery-mode resonator of FIG. 1.

FIG. 3 is a plot showing the effective nonlinearity of one embodiment of a whispering-gallery-mode resonator of FIG. 1 made of lithium niobate.

FIG. 4 is cross-section of the system of FIG. 1.

FIG. 5 is a zoomed-in portion of the cross-section of FIG. 1.

FIGS. 6-8 are a cross-section of the system of FIG. 1 at different points of a microwave cycle of the microwave resonator of FIG. 1.

FIG. 9 is a spectrum of the microwave resonator of FIG. 1.

FIG. 10 is a simplified diagram of a system for dual-frequency combs.

FIG. 11 is a spectrum of the dual-frequency combs that can be generated by the system of FIG. 10.

FIG. 12 is a plot of single sideband noise of the dual-frequency combs that can be generated by the system of FIG. 10.

FIG. 13 is a simplified diagram of a microwave resonator with a gap between a central component and an outer component.

FIG. 14 is a cross-section of the microwave resonator of FIG. 13.

FIG. 15 is a simplified diagram of a microwave resonator with an outer component separated into several components.

FIG. 16 is a simplified diagram of a microwave resonator with a piezoelectric transducer inside of it.

### DETAILED DESCRIPTION OF THE DRAWINGS

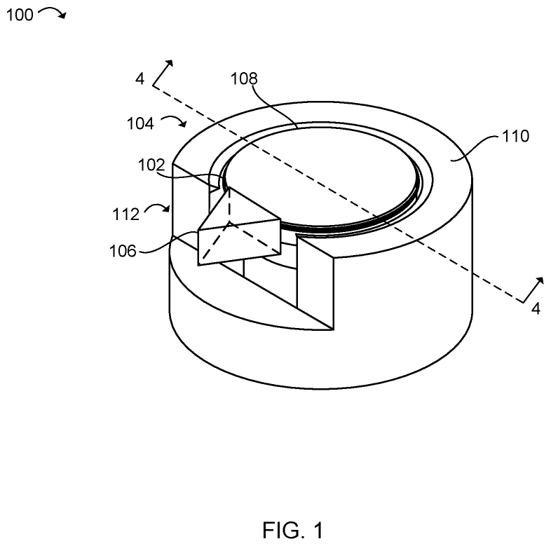

In one embodiment disclosed herein, a whispering-gallery-mode resonator (such as whispering-gallery-mode resonator 102 in FIG. 1) supports several axially-polarized modes separated by a free-spectral range (FSR) and several radially-polarized modes separated by a different free spectral range. One radially-polarized mode and one axially-polarized mode is excited using one or more optical sources. A microwave field is applied at the frequency of the FSR for the axially-polarized modes and the frequency of the FSR for the radially-polarized modes. The microwave fields couple light in the initial radially-polarized and axially-polarized modes to multiple radially-polarized and axially-polarized modes, respectively, creating a frequency comb inside the resonator for both the axially-polarized modes and the radially-polarized modes. The modes in the whispering-gallery-mode resonator can be coupled out into free space to be used for, e.g., spectroscopy, range-finding, etc.

Reference is now made to the drawings, wherein similar or same numbers may be used to designate the same or similar parts in different figures. The use of similar or same numbers in different figures does not mean all figures including similar or same numbers constitute a single or same embodiment. In the following description, for purposes of explanation, numerous specific details are set forth in order to provide a thorough understanding thereof. It may be evident, however, that the novel embodiments can be practiced without these specific details. In other instances, well-known structures and devices are shown in block diagram form to facilitate a description thereof. The intention is to cover all modifications, equivalents, and alternatives within the scope of the claims.

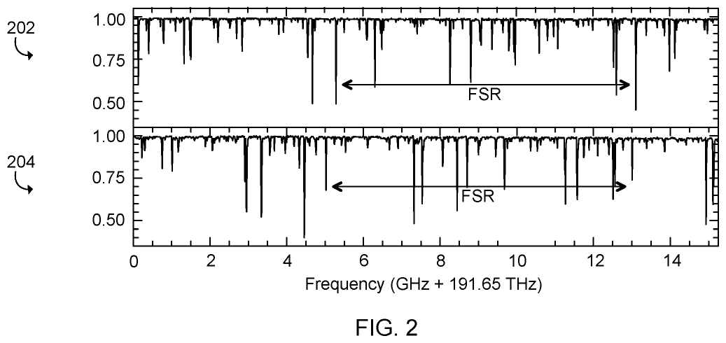

Referring now to FIG. 1, in one embodiment, an illustrative system 100 shown in FIG. 1 includes a whispering-gallery-mode resonator 102, a microwave resonator 104, and a coupling prism 106. In the illustrative embodiment, the whispering-gallery-mode resonator 102 is a ring-shaped microresonator. The resonator 102 can support two optical mode families with different free spectral ranges (FSRs): axially-polarized modes, for which the electric field is normal to the plane of the resonator 102, and radially-polarized modes, for which the electric field lies in the plane of the resonator 102. For example, a spectrum 202 of a family of radially-polarized modes and a spectrum 204 of a family of axially-polarized modes are shown in FIG. 2. The modes in each family are approximately evenly spaced, allowing cascaded coupling between modes, as described in more detail below. In the illustrative embodiment, modes of the resonator 102 that are used have a wavelength near 1,550 nanometers. In other embodiments, modes of the resonator 102 with any suitable wavelength may be used, such as a wavelength of 200-20,000 nanometers. In general, any wavelength may be used for which an appropriate nonlinear material can support cascaded three-wave mixing for different families of modes, as described herein. For example, in some embodiments, modes of the resonator 102 used to generate a frequency comb may have wavelengths as high as, e.g., 1 millimeter. In the illustrative embodiment, the Q-factor for the modes of the resonator 102 that are used is about 108. In other embodiments, modes with any suitable Q-factor may be used, such as 104-1010. Of course, attainable Q-factors may depend on a particular material absorption, surface roughness, etc.

In the illustrative embodiment, the resonator 102 is made from x-cut lithium niobate (LiNbO₃). As the orientation of the crystal changes relative to electric field of the radially-polarized modes around the resonator 102, the wavevector of the radially-polarized modes also changes around the resonator 102. In the illustrative embodiment, the coupling prism 106 is placed at a position where the wavevectors of the radially-polarized modes are about the same as the wavevectors of the axially-polarized modes, allowing free-space modes with different polarization and the same angle of incidence to couple to the resonator 102 at the same time. In other embodiments, other nonlinear crystals may be used. Any suitable crystal may be used, such as x-cut lithium tantalate, x-cut beta barium borate (BBO), x- or y-cut potassium titanyl phosphate (KTP), (110) gallium arsenide, etc.

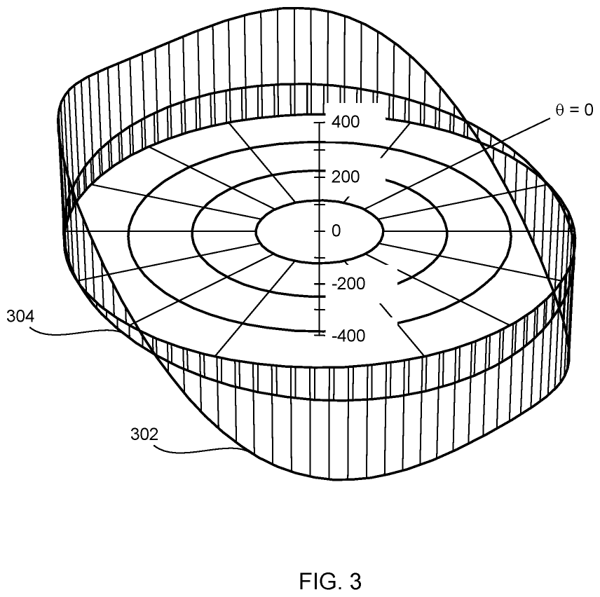

In the illustrative embodiment, the lack of rotational symmetry of the crystal around an axis of the resonator 102 facilitates phase-matching of the nonlinear interactions. For example, the angle-dependent effective nonlinearity of the resonator 102 is shown in FIG. 3 as plot 302 and plot 304 for radially-polarized and axially-polarized modes, respectively, for one resonator 102 made from lithium niobate. The units for the plots 302, 304 in FIG. 3 are picometers per volt. In some embodiments, the normal of the plane of the whispering-gallery-mode resonator 102 is an eigenvector of the linear permittivity tensor of the crystal. In embodiments with a uniaxial crystal, the optic axis is in the plane of the resonator 102. However, in other embodiments, phase-matching may be achieved with a crystal that is rotationally-symmetric about an axis of the resonator 102. For example, a spatially-varying microwave or DC electric field may facilitate phase-matching, in some embodiments.

The resonator 102 may have any suitable size or dimension. In the illustrative embodiment, the resonator 102 is a ring with a major radius of 2.56 millimeters and a minor radius of 400 micrometers. More generally, the resonator 102 may have any suitable major diameter, such as 0.2-10 millimeters. In some embodiments, the resonator 102 may be a microring or microdisk resonator with a diameter of, e.g., 5-500 micrometers. In the illustrative embodiment, the spacing between lines corresponds to the separation between adjacent modes in a family of modes, i.e., the free-spectral range. The free spectral range, in turn, depends on the diameter of the resonator 102. In the illustrative embodiment, the FSR for the axially-polarized modes is 7.814 gigahertz, and the FSR for the radially-polarized modes is 7.934 gigahertz. More generally, the FSRs for the radially-polarized and/or axially-polarized modes may be any suitable value, such as 0.1-10,000 gigahertz.

In the illustrative embodiment, the resonator 102 may be made using mechanical polishing. For example, in one embodiment, a relatively large ring of material of lithium niobate is mounted on the central component 108 using an adhesive. The lithium niobate is then mechanically removed and polished using, e.g., a lathe, forming the whispering-gallery-mode resonator 102. In other embodiments, the resonator 102 may be made in another manner, such as using photolithography techniques or femtosecond laser machining.

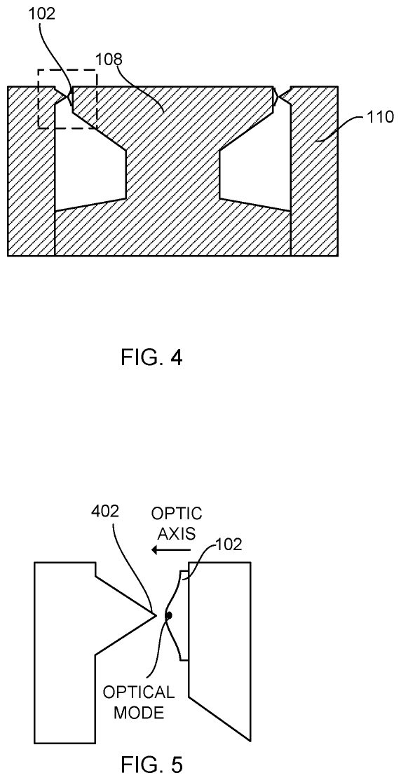

In the illustrative embodiment, the microwave resonator 104 is a toroidal loop-gap resonator (i.e., a torus with a slit gap in the top). The microwave resonator 104 has a central component 108 and an outer component 110. In the illustrative embodiment, the whispering-gallery-mode resonator 102 is mounted on the central component 108. The illustrative outer component 110 has a protrusion 402 (see FIGS. 4 and 5) extending from the outer component 110 towards the central component 108, which concentrates the electric field near the modes in the whispering-gallery-mode resonator 102.

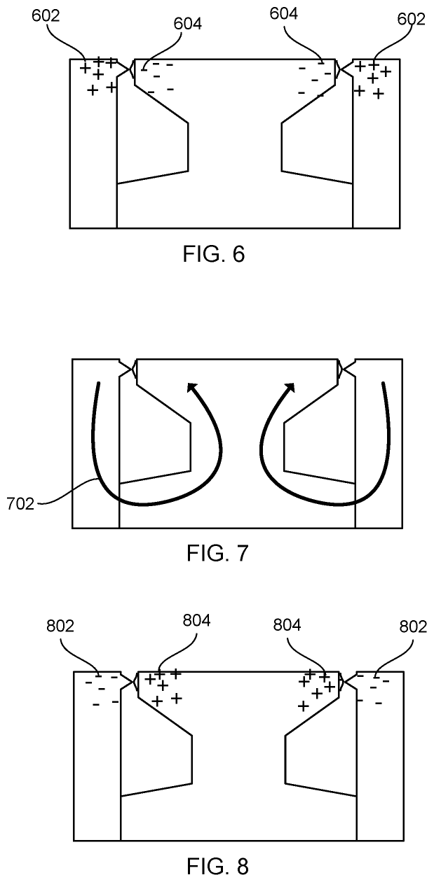

In use, the microwave resonator 104 is excited by one or more microwave fields. In one cycle of the microwave resonator 104, a positive charge 602 is concentrated on the outer component 110, and a negative charge 604 is concentrated on the central component 108, as shown in FIG. 6. Electric field lines extend radially between the central component 108 and the outer component 110, through the whispering-gallery-mode resonator 102. As the microwave resonator 104 is rotationally symmetric (ignoring the effect of the cut-out region 112 for the prism 106, discussed below), the whispering-gallery-mode resonator 102 experiences a radial electric field that is not spatially dependent.

Continuing a cycle of the microwave resonator, current 702 flows in the form of the positive charge 602 in the outer component 110 to the negative charge 604 in the central component 110, as shown in FIG. 7. At this time, the whispering-gallery-mode resonator 102 experiences essentially zero electric field.

As the current 702 continue, negative charge 802 accrues in the outer component 110, and positive charge 804 accrues in the central component 108, as shown in FIG. 8. At this time, the whispering-gallery-mode resonator 102 again experiences a radial electric field, but this time in the opposite direction. The cycle of the microwave resonator continues with a current flowing from the central component 108 back to the outer component 110, leading back to the situation shown in FIG. 6.

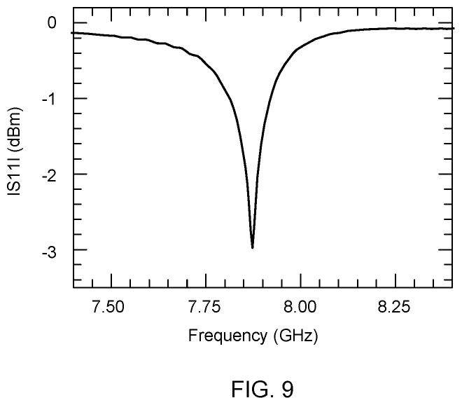

A spectrum of the microwave resonator 104 is shown in FIG. 9. In the illustrative embodiment, the microwave resonator has a mode frequency centered at about 7.9 gigahertz, near the FSRs for the axially-polarized and radially-polarized modes of the whispering-gallery-mode resonator 102. The microwave resonator 104 has a bandwidth of about 200 megahertz. As such, the microwave resonator 104 can support a microwave signal at both the FSR for radially-polarized modes and the FSR for radially-polarized modes. More generally, the microwave resonator 104 can support a mode with any suitable center frequency and any suitable bandwidth, such as a center frequency of 0.1-20,000 gigahertz and a bandwidth of 0.01-1,000 gigahertz.

In the illustrative embodiment, the microwave resonator 104 is made of two or more components that are mated together. For example, in the illustrative embodiment, the central component 108 is formed separately and mated together with the outer component 110. In some embodiments, the outer component 110 itself may be made up of two or more components mated together.

In the illustrative embodiment, the microwave resonator 104 is made out of copper. In other embodiments, the microwave resonator may be made out of an suitable material, such as aluminum, iron, gold, etc.

In the illustrative embodiment, there is air between the protrusion 402 of the outer component 110 and the central component 108. In other embodiments, the gap between the outer component 110 and the central component 108 may be filled with a solid or liquid dielectric.

The prism 106 is configured to couple light into and out of the whispering-gallery-mode resonator 102. In the illustrative embodiment, the prism 106 is made from a material with a relatively high index of refraction, such as diamond. More generally, the prism 106 has an index of refraction that is at least as high as that of the whispering-gallery-mode resonator 102 in order to be able to couple light into and out of it.

The prism 106 is positioned in a cut-out region 112 of the outer component 110 of the microwave resonator 104. As current does not flow through the cut-out region 112 as it does in the rest of the microwave resonator 104, the microwave field is not applied in the region of the prism 106. However, in the illustrative embodiment, the prism 106 is located near a zero-crossing in the effective nonlinearity of the whispering-gallery-mode resonator 102. As a result, the lack of microwave electric field in the cut-out region 112 does not significantly reduce coupling between modes in the resonator 102.

In the illustrative embodiment, the microwave resonator 104 serves to both increase the electric field applied to the whispering-gallery-mode resonator 102 and apply a uniform radial electric field to the resonator 102 (except for the cut-out region 112). However, in some embodiments, a different-shaped microwave resonator 104 (such as a loop-gap resonator) or no resonator 104 may be used. For example, a microwave electric field may be applied in free space or with use of one or more electrodes.

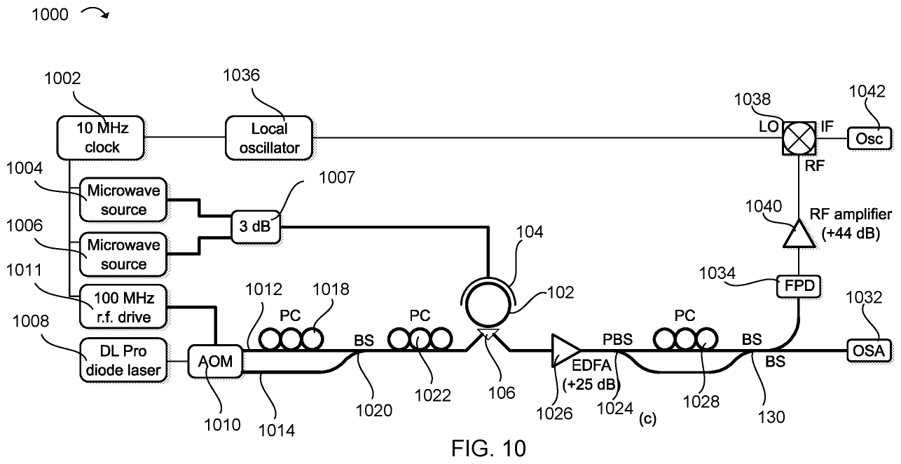

Referring now to FIG. 10, in one embodiment, a system 1000 includes the whispering-gallery-mode resonator 102, the microwave resonator 104, and the prism 106. The system 1000 also includes a clock 1002, a first microwave source 1004, a second microwave source 1006, a laser 1008, an acousto-optic modulator (AOM) 1010, and a driver 1011 for the AOM 1010. A beam from the laser 1008 passes through the AOM 1010, creating a first beam 1014 with a first frequency and a second beam 1016 with a second frequency. The second frequency is detuned from the first frequency by the driving frequency of the driver 1011, which, in the illustrative embodiment, is 100 megahertz. In some embodiments, a temperature of the whispering-gallery-mode resonator may be stabilized using, e.g., a temperature controller and a heating device.

The first beam 1014 passes through a first polarization controller 1018 and combines with the second beam 1016 at a splitter 1020. The light beams 1014, 1016 then pass through a second polarization controller 1022 and are coupled into free space, such as by using a gradient-index (grin) lens and then into the whispering-gallery-mode resonator 102 using the prism 106. In other embodiments, the beams 1014, 1016 may be coupled into the whispering-gallery-mode resonator 102 using, e.g., a tapered fiber. The polarization controllers 1018, 1022 are used to orient the first beam 1014 and second beam 1014 to excite a radially-polarized and axially-polarized mode, respectively, in the whispering-gallery-mode resonator 102.

In use, the microwave sources 1004, 1006 are combined at a 3 dB splitter 1007 and drive the microwave resonator 104 using a coupled antenna. In the illustrative embodiment, the power of each microwave source 1004, 1006 is 35 dBm. In other embodiments, other microwave power may be used, such as 10-50 dBm. The microwave field set to the frequency of the FSR of the radially-polarized modes couples the light in the radially-polarized mode to adjacent radially-polarized modes through sum—and difference—frequency generation using the second-order (or electro-optic) x⁽²⁾ nonlinearity of the whispering-gallery-mode resonator 102. The coupling strength depends on the effective nonlinearity and the strength of the microwave field. As noted above, the microwave field and optical fields are symmetric, and the azimuthal dependence on the effective nonlinearity depicted in FIG. 2 facilitates phase matching between the modes. The microwave field set to the frequency of the FSR of the axially-polarized modes couples the light in the axially-polarized mode to adjacent axially-polarized modes in a similar manner.

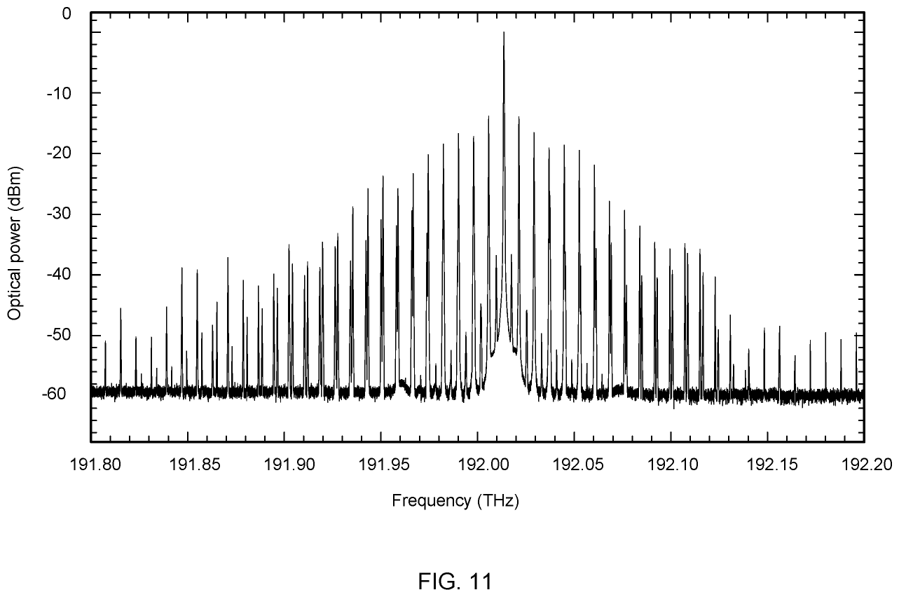

In the illustrative embodiment, the resulting spectrum 1100 measured on an optical spectrum analyzer 1032 is shown in FIG. 11. The spectrum 1100 shows two frequency combs with slightly different spacing between lines, corresponding to the different free spectral ranges between the radially-polarized modes and axially-polarized modes. The longer comb, with more than 50 visible comb lines, forms in the radially-polarized mode family, while the axially-polarized comb is shorter due to its lower effective x⁽²⁾. The spectrum 1100 includes several lines near the line of the laser 1008, which are from the laser 1008 itself and not part of the comb structure.

It should be appreciated that several of the components shown in FIG. 10 may be used for characterizing the noise, linewidths, etc., of the frequency combs created but are not critical for creating the frequency combs themselves. As such, in some embodiments, some of the components such as the photodiode 1034, the local oscillator 1036, the mixer 1038, etc., may be removed or replaced with other components.

A key advantage of dual-comb techniques is that the combs can traverse spatially separated paths, and then be referenced against each other by mixing them down to radio-band frequencies with a fast photodiode. This requires that they can be separated into ‘probe’ and ‘reference’ combs. As the two families of modes in the system 1000 are orthogonally-polarized, they can be easily separated, despite the overlap in frequency. For example, in the illustrative embodiment, the beams can be split using a polarizing beamsplitter 1024. An amplifier, such as an erbium-doped fiber amplifier 1026 may be inserted in order increase the power of the combs before measurement. In order to mix the combs together, the reference comb polarization can be rotated using another polarization controller 1028 and then combined with the probe comb at a (nonpolarizing) beamsplitter 1030 before being detected at a fast photodiode 1034. In some embodiments, an output of the photodiode 1034 is used as feedback to control the microwave sources 1004, 1006.

In the illustrative embodiment, the microwave sources 1004, 1006 providing the comb spacing frequencies, and the driver 1011 driving the AOM 1010 are locked to the same 10 MHz clock signal from the clock 1002, allowing accurate assessment of the phase noise due to optical noise in the resonator 102. That phase noise can be measured by mixing the beat tone of two comb lines (after amplification at an amplifier 1040) with a local oscillator 1036 at a mixer 1038, which is locked to the clock signal from the clock 1002. In the illustrative embodiment, the line of the comb with the highest intensity is the line corresponding to the input beams 1012, 1014. That line may be referred to as the zeroth order line, and each line n FSRs away from the zeroth order line may be referred to as the (positive or negative) nth order line. The local oscillator 1036 is detuned (e.g., about 100 Hertz) from the beat note of interest. The output of the mixer 1038 generates an intermediate frequency (IF) at the detuning of the local oscillator 1036 relative to the beat note of interest (e.g., about 100 Hz), which is sampled at a frequency of 10 kHz at an oscilloscope 1042. The IF can be sampled for any suitable amount of time, such as 1 second to 100 minutes. In the illustrative embodiment, the IF is sampled for 107 samples, or 16 minutes and 40 seconds. The power spectrum of the IF signal is then calculated.

For investigating the noise of two arbitrary comb lines, the oscillator 1036 can be detuned from the expected beat note. For example, the expected beat note for the nth order pair of lines is n times the difference in the free spectral ranges plus or difference in frequency between the zeroth order lines.

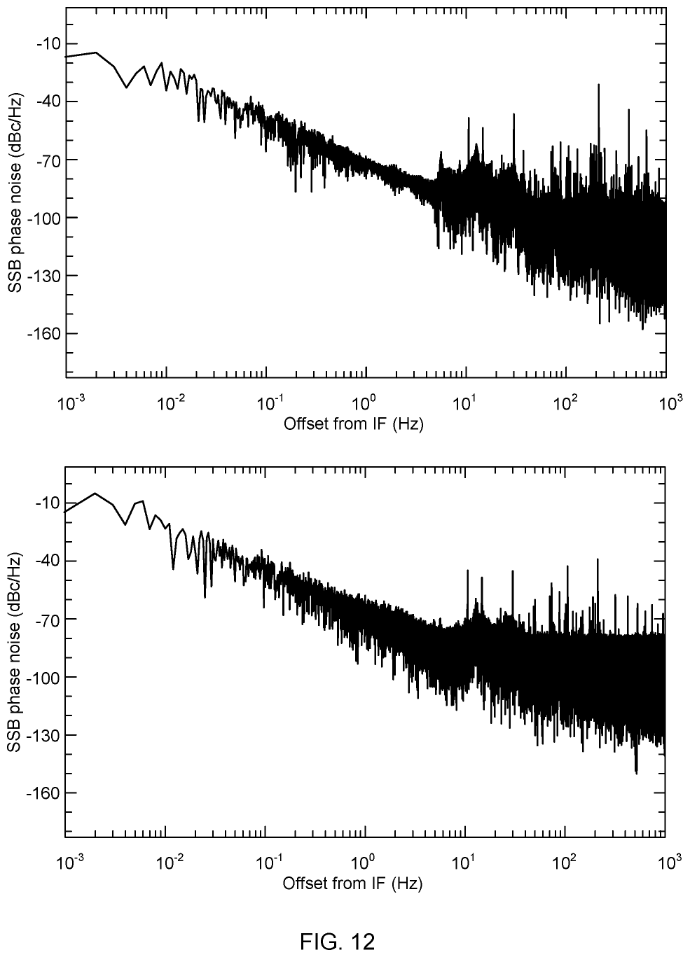

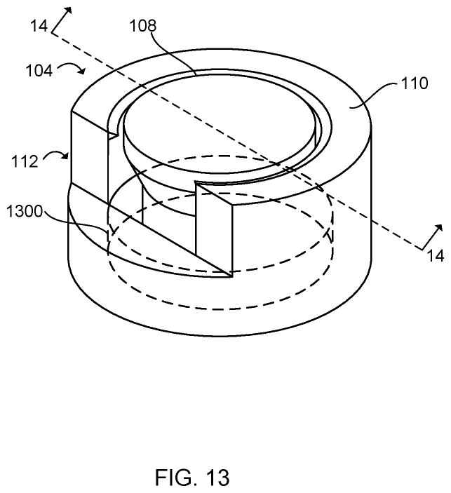

FIG. 12 shows the single sideband phase noise for the zeroth order IF (top), resulting from the two optical carriers separated by 100 MHz, and the first order IF (bottom), generated by comb lines separated by 20 MHz. An IF linewidth of 0.217±0.096 millihertz is measured for the zeroth order beat note between the two carriers. That noise originates from uncorrelated noise on the two fiber arms of the output of the AOM 1010. In the illustrative embodiment, the relative linewidth of the beat note of the first order line of one comb and the first order line of the second comb is less than 0.5 millihertz. In other embodiments, the relative linewidth of the beat note of the first order line of one comb and the first order line of the second comb may be, e.g., 0.1-100 millihertz.

The dual-frequency comb source 1000 may be used for any suitable application. For example, the dual-frequency comb source 1000 may form a part of or other be included in a range-finding system, a light detection and ranging (LIDAR) system, a spectroscopy system, etc. In one embodiment, the dual-frequency comb source 1000 may be used for range-finding on a satellite orbiting Earth.

It should be appreciated that variants of the techniques disclosed herein are envisioned as well. For example, in one embodiment, the whispering-gallery-mode resonator 102 may have a radially-polarized and axially-polarized counter-propagating pump, creating two additional frequency combs. As those combs are travelling in the other direction, they would be easily separable from the two frequency combs in the counter-propagating direction. Additionally, the counter-propagating beams would respond differently to a change in rotation of the resonator 102, allowing the system 1000 to sense rotation and act as a gyroscope. Additionally, such a set of frequency combs could be used for, e.g., multidimensional coherent spectroscopy or ambiguity-free range finding.

Additionally or alternatively, in some embodiments, different families of modes with, e.g., different numbers of lobes along a polar angle, may be populated independently, leading to a large number of frequency combs in orthogonal spatial modes. As the spatial modes are orthogonal, they can be separated after being coupled out of the resonator 102.

As another example, a second prism 106 can be coupled to the resonator 102 on the opposite side of the first prism 106. The second prism 106 can couple out the dual-frequency combs without any contribution from the part of the beams 1012, 1014 not coupled to the resonator 102

In the illustrative embodiment, the modes in the resonator 104 are coupled using a x⁽²⁾ nonlinearity. In some embodiments, the nonlinearity of the whispering-gallery-mode resonator 102 that is used may be a x⁽³⁾ (or Kerr) nonlinearity. For example, a DC electric field may combine with the microwave and optical fields to perform a similar cascaded sum—and difference—frequency generation using a x⁽³⁾ nonlinearity.

In other embodiments, frequency combs generated by, e.g., the system 1000 may be used in an optical computing system, in which controllable nonlinear interactions between different comb lines can be used as a basis for computing. In some embodiments, different comb lines can be entangled, allowing for quantum computing (such as a quantum neural network) to be implemented using the system 1000. In still other embodiments, different comb lines may be used to simulate synthetic dimensions.

In some embodiments, the whispering-gallery-mode resonator 102 may have a small enough minor radius to only support a single polar mode. In such embodiment, the spectrum of the whispering-gallery-mode resonator 102 will be relatively sparse, which can reduce undesired coupling between nearby modes and increase the bandwidth of the resulting combs.

In some embodiments, frequency combs generated by the system 1000 may be used to perform dispersive flow rate measurements. The Doppler shift caused by changes in flow rates can be sensed and used to determine the flow rate.

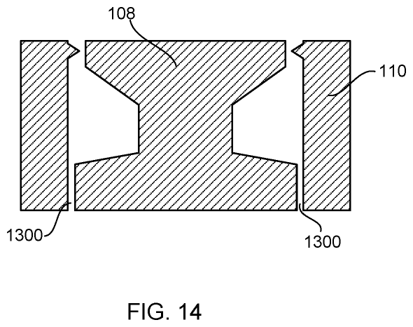

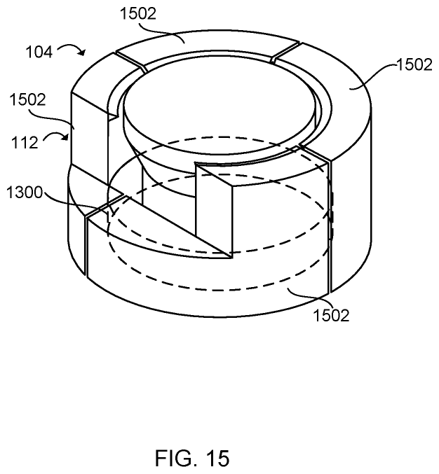

In the illustrative embodiment, the components 108, 110 of the microwave resonator 104 are in contact and, therefore, are at the same potential. In other embodiments, the central component 108 may be separated from the outer component 110 by a gap, such as shown in FIG. 13, a cross-section of which is shown in FIG. 14. As shown in FIGS. 13 and 14, a gap 1302 can separate the central component 108 from the outer component 110. As the central component 108 is not connected to the outer component 110, the central component 108 can be held at a different potential from the outer component 110. The difference in potential between the central component 108 and the outer component 110 will cause a DC electric field to be present at the interface between the central component 108 and the outer component 110, both at the gap 1302 and at the gap near the top of the resonator 104 wherein the whispering-gallery-mode resonator 102 is. As a result, the whispering-gallery-mode resonator 102 will be subject to a controllable DC electric, which can be used to tune various parameters of the system 1000, such as the phase matching of the three-wave-mixing processes. In some embodiments, a dielectric may be placed in the gap 1302.

In other embodiments, the outer component 110 can be split into two or more outer components 1502, as shown in FIG. 15. Each outer component 1502 can be held to a different potential. Such an approach would allow a different electric field to be applied to different sections of the whispering-gallery-mode resonator 102, which would be similar to periodic poling in a bulk crystal. The outer component 110 may be split up into any suitable number of outer components 1502, such as 2-32. Each outer component 1502 have be the same size (i.e., span the same arc length), or some or all of the outer components 1502 may be different sizes (i.e., span different arc lengths).

In some embodiments, the microwave resonator 104 may be driven at higher order modes than the fundamental. Different higher order modes may be used to drive families of modes in the whispering-gallery-mode resonator 104 with different free spectral ranges. Additionally or alternatively, higher order modes may be used to couple modes of a family that are separated by more than one free spectral range.

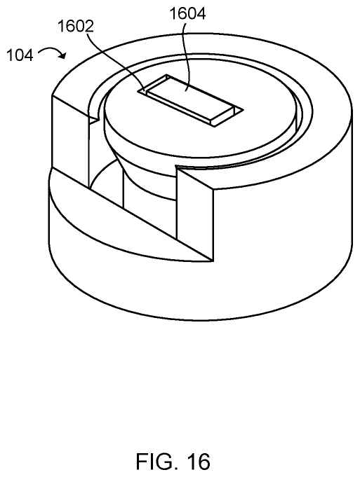

In some embodiments, the microwave resonator 104 may have an opening 1602 cut in it, into which a piezoelectric transducer 1604 is placed, as shown in FIG. 16. The piezoelectric transducer 1604 may have a voltage placed across it, deforming the microwave resonator 104 and the whispering-gallery-mode resonator 102. The deformation of the whispering-gallery-mode resonator 102 can be used to tune the phase matching of the three-wave-mixing process in the whispering-gallery-mode resonator 102.

As used in this application and in the claims, a list of items joined by the term “and/or” can mean any combination of the listed items. For example, the phrase “A, B and/or C” can mean A; B; C; A and B; A and C; B and C; or A, B and C. As used in this application and in the claims, a list of items joined by the term “at least one of” can mean any combination of the listed terms. For example, the phrase “at least one of A, B or C” can mean A; B; C; A and B; A and C; B and C; or A, B and C. Moreover, as used in this application and in the claims, a list of items joined by the term “one or more of” can mean any combination of the listed terms. For example, the phrase “one or more of A, B and C” can mean A; B; C; A and B; A and C; B and C; or A, B, and C.

The disclosed methods, apparatuses and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

### EXAMPLES

Illustrative examples of the technologies disclosed herein are provided below. An embodiment of the technologies may include any one or more, and any combination of, the examples described below.

Example 1 includes a system comprising an optical resonator, wherein the optical resonator has a non-zero x(2) nonlinearity, wherein the optical resonator supports a plurality of radially-polarized spatial modes and a plurality of axially-polarized spatial modes, wherein the plurality of radially-polarized spatial modes has a first free spectral range (FSR) and the plurality of axially-polarized spatial modes has a second FSR; one or more optical sources coupled to a radially-polarized spatial mode of the plurality of radially-polarized spatial modes and to an axially-polarized spatial mode of the plurality of axially-polarized spatial modes; and one or more microwave source that applies a first microwave field and a second microwave field to at least part of the optical resonator, wherein the first microwave field has a frequency approximately equal to the first FSR and the second microwave field has a frequency approximately equal to the second FSR, wherein light in the radially-polarized spatial mode mixes with the first microwave field to populate other radially-polarized spatial modes of the plurality of radially-polarized spatial modes, wherein light in the axially-polarized spatial mode mixes with the second microwave field to populate other axially-polarized spatial modes of the plurality of axially-polarized spatial modes.

Example 2 includes the subject matter of Example 1, and wherein the plurality of radially-polarized spatial modes are coupled to a free-space mode, wherein light from the plurality of radially-polarized spatial modes form a first frequency comb, wherein the plurality of axially-polarized spatial modes are coupled to a free-space mode, wherein light from the plurality of axially-polarized spatial modes form a second frequency comb.

Example 3 includes the subject matter of any of Examples 1 and 2, and wherein a zeroth order line and a first order line of the first frequency comb have a beat linewidth less than 1 millihertz, wherein a zeroth order line and a first order line of the second frequency comb have a beat linewidth less than 1 millihertz.

Example 4 includes the subject matter of any of Examples 1-3, and wherein a relative linewidth between a first order line of the first frequency comb and a first order line the second frequency comb is less than 0.5 millihertz.

Example 5 includes the subject matter of any of Examples 1-4, and wherein the first frequency comb comprises at least twenty lines, wherein each of the at least twenty lines of the first frequency comb has a power at least-30 dB relative to a zeroth order line of the first frequency comb, wherein the second frequency comb comprises at least twenty lines, wherein each of the at least twenty lines of the second frequency comb has a power at least-30 dB relative to a zeroth order line of the second frequency comb,

Example 6 includes the subject matter of any of Examples 1-5, and wherein the system comprises a range finding system, wherein the range finding system is to use the first frequency comb and the second frequency comb for range finding.

Example 7 includes the subject matter of any of Examples 1-6, and wherein the system comprises a light detection and ranging (LIDAR) system, wherein the LIDAR system is to use the first frequency comb and the second frequency comb for range finding.

Example 8 includes the subject matter of any of Examples 1-7, and wherein the system comprises spectroscopy system, wherein the spectroscopy system is to use the first frequency comb and the second frequency comb for spectroscopy.

Example 9 includes the subject matter of any of Examples 1-8, and wherein the first frequency comb has a polarization that is orthogonal to a polarization of the frequency second comb.

Example 10 includes the subject matter of any of Examples 1-9, and wherein the optical resonator is lithium niobate.

Example 11 includes the subject matter of any of Examples 1-10, and wherein the one or more optical sources have a wavelength between 200 nanometers and 20,000 nanometers.

Example 12 includes the subject matter of any of Examples 1-11, and further including a microwave resonator, wherein the microwave source applies the first microwave field and the second microwave field to the microwave resonator, wherein the microwave resonator is a toroidal loop-gap resonator, wherein the optical resonator is positioned in a gap of the toroidal loop-gap resonator.

Example 13 includes a system comprising a whispering-gallery-mode resonator, wherein the whispering-gallery-mode resonator has a non-zero x(2) nonlinearity, wherein the whispering-gallery-mode resonator supports a plurality of radially-polarized spatial modes and a plurality of axially-polarized spatial modes, wherein the plurality of radially-polarized spatial modes has a first free spectral range (FSR) and the plurality of axially-polarized spatial modes has a second FSR; a microwave resonator, the microwave resonator comprising a capacitive region, wherein the whispering-gallery-mode resonator is positioned in the capacitive region, wherein the microwave resonator has a fundamental mode with a bandwidth that is greater than a difference between the first FSR and the second FSR; one or more optical sources configured to be coupled to a radially-polarized spatial mode of the plurality of radially-polarized spatial modes and to an axially-polarized spatial mode of the plurality of axially-polarized spatial modes; and one or more microwave sources coupled to the microwave resonator, wherein the one or more microwave sources is configured to drive the microwave resonator at the first FSR and at the second FSR.

Example 14 includes the subject matter of Example 13, and wherein the whispering-gallery-mode resonator is made from a uniaxial crystal, wherein an optic axis of the whispering-gallery-mode resonator is in a plane defined by the plurality of radially-polarized spatial modes.

Example 15 includes the subject matter of any of Examples 13 and 14, and wherein the whispering-gallery-mode resonator is lithium niobate.

Example 16 includes the subject matter of any of Examples 13-15, and wherein the one or more optical sources have a wavelength between 200 nanometers and 20,000 nanometers.

Example 17 includes the subject matter of any of Examples 13-16, and wherein the microwave resonator is a toroidal loop-gap resonator, wherein at least part of the whispering-gallery-mode resonator is positioned in a gap of the toroidal loop-gap resonator.

Example 18 includes the subject matter of any of Examples 13-17, and further including a DC bias source to apply a DC electric field bias to the whispering-gallery-mode resonator.

Example 19 includes the subject matter of any of Examples 13-18, and further including a temperature controller to control a temperature of the whispering-gallery-mode resonator.

Example 20 includes the subject matter of any of Examples 13-19, and wherein the one or more optical sources populate a free space mode, further comprising a prism to couple each of the plurality of axially-polarized spatial modes to free space modes that overlap with the free space mode and couple each of the plurality of radially-polarized spatial modes to free space modes that overlap with the free space mode.

Example 21 includes a method comprising coupling one or more optical sources to a radially-polarized mode of a plurality of radially-polarized spatial modes of a nonlinear optical resonator; coupling the one or more optical sources to an axially-polarized mode of a plurality of axially-polarized spatial modes of the nonlinear optical resonator; applying a first microwave field to the nonlinear optical resonator to mix light in the radially-polarized mode to populate other radially-polarized spatial modes of the plurality of radially-polarized spatial modes; and applying a second microwave field to the nonlinear optical resonator to mix light in the axially-polarized mode to populate other axially-polarized spatial modes of the plurality of axially-polarized spatial modes.

Example 22 includes the subject matter of Example 21, and further including coupling the plurality of radially-polarized spatial modes to a free-space mode, wherein light from the plurality of radially-polarized spatial modes form a first frequency comb, coupling the plurality of axially-polarized spatial modes to a free-space mode, wherein light from the plurality of axially-polarized spatial modes form a second frequency comb.

Example 23 includes the subject matter of any of Examples 21 and 22, and wherein the first frequency comb has a beat linewidth less than 1 millihertz, wherein the second frequency comb has a beat linewidth less than 1 millihertz.

Example 24 includes the subject matter of any of Examples 21-23, and wherein a relative linewidth between the first frequency comb and the second frequency comb is less than 0.5 millihertz.

Example 25 includes the subject matter of any of Examples 21-24, and wherein the first frequency comb has a polarization that is orthogonal to a polarization of the second frequency comb.

Example 26 includes the subject matter of any of Examples 21-25, and further including using the first frequency comb and the second frequency comb in a range finding system.

1-26. (canceled)

27. A system comprising:
an optical resonator, wherein the optical resonator has a non-zero x⁽²⁾ nonlinearity, wherein the optical resonator supports a plurality of radially-polarized spatial modes and a plurality of axially-polarized spatial modes, wherein the plurality of radially-polarized spatial modes has a first free spectral range (FSR) and the plurality of axially-polarized spatial modes has a second FSR;
one or more optical sources coupled to a radially-polarized spatial mode of the plurality of radially-polarized spatial modes and to an axially-polarized spatial mode of the plurality of axially-polarized spatial modes; and
one or more microwave sources that applies a first microwave field and a second microwave field to at least part of the optical resonator, wherein the first microwave field has a frequency approximately equal to the first FSR and the second microwave field has a frequency approximately equal to the second FSR,
wherein light in the radially-polarized spatial mode mixes with the first microwave field to populate other radially-polarized spatial modes of the plurality of radially-polarized spatial modes,
wherein light in the axially-polarized spatial mode mixes with the second microwave field to populate other axially-polarized spatial modes of the plurality of axially-polarized spatial modes.

28. The system of claim 27, wherein the plurality of radially-polarized spatial modes are coupled to a free-space mode, wherein light from the plurality of radially-polarized spatial modes form a first frequency comb,
wherein the plurality of axially-polarized spatial modes are coupled to a free-space mode, wherein light from the plurality of axially-polarized spatial modes form a second frequency comb.

29. The system of claim 28, wherein a zeroth order line and a first order line of the first frequency comb have a beat linewidth less than 1 millihertz, wherein a zeroth order line and a first order line of the second frequency comb have a beat linewidth less than 1 millihertz.

30. The system of claim 28, wherein a relative linewidth between a first order line of the first frequency comb and a first order line the second frequency comb is less than 0.5 millihertz.

31. The system of claim 28, wherein the first frequency comb comprises at least twenty lines, wherein each of the at least twenty lines of the first frequency comb has a power at least-30 dB relative to a zeroth order line of the first frequency comb,
wherein the second frequency comb comprises at least twenty lines, wherein each of the at least twenty lines of the second frequency comb has a power at least-30 dB relative to a zeroth order line of the second frequency comb.

32. The system of claim 28, wherein the system comprises a range finding system, wherein the range finding system is to use the first frequency comb and the second frequency comb for range finding.

33. The system of claim 28, wherein the system comprises a light detection and ranging (LIDAR) system, wherein the LIDAR system is to use the first frequency comb and the second frequency comb for range finding.

34. The system of claim 28, wherein the system comprises spectroscopy system, wherein the spectroscopy system is to use the first frequency comb and the second frequency comb for spectroscopy.

35. The system of claim 28, wherein the first frequency comb has a polarization that is orthogonal to a polarization of the second frequency comb.

36. The system of claim 27, wherein the optical resonator is lithium niobate.

37. The system of claim 27, wherein the one or more optical sources have a wavelength between 200 nanometers and 20,000 nanometers.

38. The system of claim 27, further comprising a microwave resonator,
wherein the one or more microwave sources apply the first microwave field and the second microwave field to the microwave resonator,
wherein the microwave resonator is a toroidal loop-gap resonator, wherein the optical resonator is positioned in a gap of the toroidal loop-gap resonator.

39. A system comprising:
a whispering-gallery-mode resonator, wherein the whispering-gallery-mode resonator has a non-zero x⁽²⁾ nonlinearity, wherein the whispering-gallery-mode resonator supports a plurality of radially-polarized spatial modes and a plurality of axially-polarized spatial modes, wherein the plurality of radially-polarized spatial modes has a first free spectral range (FSR) and the plurality of axially-polarized spatial modes has a second FSR;
a microwave resonator, the microwave resonator comprising a capacitive region, wherein the whispering-gallery-mode resonator is positioned in the capacitive region, wherein the microwave resonator has a fundamental mode with a bandwidth that is greater than a difference between the first FSR and the second FSR;
one or more optical sources configured to be coupled to a radially-polarized spatial mode of the plurality of radially-polarized spatial modes and to an axially-polarized spatial mode of the plurality of axially-polarized spatial modes; and
one or more microwave sources coupled to the microwave resonator, wherein the one or more microwave sources are configured to drive the microwave resonator at the first FSR and at the second FSR.

40. The system of claim 39,
wherein the whispering-gallery-mode resonator is made from a uniaxial crystal,
wherein an optic axis of the whispering-gallery-mode resonator is in a plane defined by the plurality of radially-polarized spatial modes.

41. The system of claim 39, wherein the whispering-gallery-mode resonator is lithium niobate.

42. The system of claim 39, wherein the microwave resonator is a toroidal loop-gap resonator, wherein at least part of the whispering-gallery-mode resonator is positioned in a gap of the toroidal loop-gap resonator.

43. The system of claim 39, wherein the one or more optical sources populate a free space mode, further comprising a prism to couple each of the plurality of axially-polarized spatial modes to free space modes that overlap with the free space mode and couple each of the plurality of radially-polarized spatial modes to free space modes that overlap with the free space mode.

44. A method comprising:
coupling one or more optical sources to a radially-polarized mode of a plurality of radially-polarized spatial modes of a nonlinear optical resonator;
coupling the one or more optical sources to an axially-polarized mode of a plurality of axially-polarized spatial modes of the nonlinear optical resonator;
applying a first microwave field to the nonlinear optical resonator to mix light in the radially-polarized mode to populate other radially-polarized spatial modes of the plurality of radially-polarized spatial modes; and
applying a second microwave field to the nonlinear optical resonator to mix light in the axially-polarized mode to populate other axially-polarized spatial modes of the plurality of axially-polarized spatial modes.

45. The method of claim 44, further comprising:
coupling the plurality of radially-polarized spatial modes to a free-space mode, wherein light from the plurality of radially-polarized spatial modes form a first frequency comb; and
coupling the plurality of axially-polarized spatial modes to a free-space mode, wherein light from the plurality of axially-polarized spatial modes form a second frequency comb.

46. The method of claim 45, further comprising using the first frequency comb and the second frequency comb in a range finding system.
